(19) United States
(12) Patent Application Publication
(10) Pub. No.: US 2012/0200995 A1
(43) Pub. Date: Aug. 9, 2012

(54) DISPLAY DEVICE HOLDING APPARATUS AND PORTABLE TERMINAL PROVIDED WITH SAME

(75) Inventor: Hiroyuki Ogihara, Tokyo (JP)

(73) Assignee: PANASONIC CORPORATION, Osaka (JP)

(21) Appl. No.: 13/501,605

(22) PCT Filed: Oct. 21, 2010
(86) PCT No.: PCT/JP2010/006251

§ 371 Date: Apr. 12, 2012

(30) Foreign Application Priority Data
Oct. 21, 2009 (JP) 2009-242600

(51) Int. Cl. G06F 1/16; H05K 7/00

(52) U.S. Cl. 361/679.26; 361/807

(57) ABSTRACT

Even when the total length of a display device is increased, the strength of a case is sufficiently ensured without increasing the total length of the case itself.

The display device holding apparatus of the invention includes: a first case; a display device which is disposed in the first case; a coupling portion which has a rib extending in a thickness direction of the first case, and which swingably couples a second case to the first case; and a sheet metal which has: a first portion that is placed in the first case, and that is substantially parallel to the thickness direction of the first case; a second portion that extends from the first portion in a longitudinal direction of the first case; and a third portion that extends from the second portion substantially parallel to the first portion, the sheet metal being molded integrally with a part of the first case, the rib is engaged with a groove disposed in the first case between the first portion and the third portion in the longitudinal direction of the first case, and the coupling portion and at least a part of the sheet metal hold the display device.

### TECHNICAL FIELD

The present invention relates to a display device holding apparatus, and a portable terminal having it.

### BACKGROUND ART

In a portable terminal 180 which is disclosed in Patent Reference 1 as a conventional example, a sheet metal for holding a display device or the like is insert-molded in a resin portion of a case 181 constituting the portable terminal 180. FIG. 6 is a view showing the structure for holding the display device in the conventional example.

In the holding structure shown in FIG. 6, the insert-molded sheet metal 185 is formed in the resin portion (in the figure, the hatched portion) of the case 181 which is screwed by a screw 184 to a hinge portion 183, and the insert sheet metal 185 and the resin portion of the case 181 have a function of holding the display device 182:

### PRIOR ART REFERENCE

### Patent Reference

Patent Reference 1: Japanese Patent No. 4,206,118

### SUMMARY OF THE INVENTION

### Problems that the Invention is to Solve

In the holding structure shown in FIG. 6, when the total length of the display device 182 is increased in the longitudinal direction (the X-axis direction in the figure) of the case 181, however, strength sufficient as a case which holds the display device 182 cannot be obtained unless the total length of the case 181 is increased. This causes the size of the portable terminal to be increased.

It is an object of the invention to provide a display device holding apparatus in which, even when the total length of a display device is increased, the strength of a case can be sufficiently ensured without increasing the total length of the case itself, and a portable terminal having it.

### Means for Solving the Problems

The invention provides a display device holding apparatus including: a first case; a display device which is disposed in the first case; a coupling portion which has a rib extending in a thickness direction of the first case, and which swingably couples a second case to the first case; and a sheet metal which has: a first portion that is placed in the first case, and that is substantially parallel to the thickness direction of the first case; a second portion that extends from the first portion in a longitudinal direction of the first case; and a third portion that extends from the second portion substantially parallel to the first portion, the sheet metal being molded integrally with a part of the first case, the rib is engaged with a groove disposed in the first case between the first portion and the third portion in the longitudinal direction of the first case, and the coupling portion and at least a part of the sheet metal hold the display device.

Furthermore, the invention provides a portable terminal including the display device holding apparatus.

### Effects of the Invention

According to the display device holding apparatus of the invention, and the portable terminal having it, even when the total length of a display device is increased, the strength of a case can be sufficiently ensured without increasing the total length of the case itself.

### BRIEF DESCRIPTION OF THE DRAWINGS

FIG. 1 is a view showing a portable telephone 1 of an embodiment of the invention, (a) is a view showing an overlapped state, (b) is a view showing a first opened state, and (c) is a view showing a second opened state.

FIG. 2 is a perspective view of a display device holding apparatus 10.

FIG. 3 is an exploded perspective view of the display device holding apparatus 10.

FIG. 4 is a perspective view as seeing a swing shaft member 50 from the rear side.

FIG. 5 is a partial sectional view taken along line V-V in FIG. 1.

FIG. 6 is a view showing a structure for holding a liquid crystal display device in a conventional example.

### MODE FOR CARRYING OUT THE INVENTION

Hereinafter, an embodiment of the invention will be described with reference to the drawings. The X-, Y-, and Z-axes shown in the figures are axes indicating an orthogonal coordinate system in which axes are perpendicular to one another, and the axes in the figures indicate the same directions.

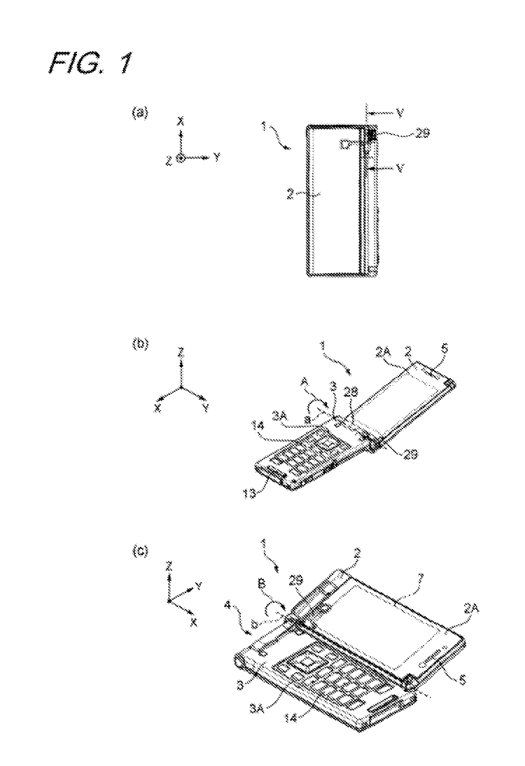

As shown in FIG. 1, as a schematic configuration, a portable telephone 1 of the embodiment include: a substantially box-like upper case 2 (a second case); a substantially box-like lower case 3 (a first case); and a coupling portion 4 which openably and closably couples the upper case 2 and the lower case 3 together. The portable telephone 1 is coupled so as to be openable and closable about an axis a in the direction (first direction) of arrow A, and perpendicular to the direction of arrow A about an axis b in the direction (second direction) of arrow B by a swinging operation of the coupling portion 4.

When to be carried, as shown in FIG. 1(a), the portable telephone 1 is used in an overlapped state (a closed state or a close state) where the upper case 2 and lower case 3 constituting the portable telephone are overlapped each other. In the case where a call is to be made, or characters, numerals, or a telephone number is to be input, for example, the portable telephone 1 is used in a first opened state (a first open state or a longitudinally opened state) where the upper case 2 is swung with respect to the lower case 3 about the axis a in the direction of arrow A (or the first direction) as shown in FIG. 1(b). In the case where a TV is to be viewed on a laterally elongated screen, for example, the portable telephone 1 is used in a second opened state (a second open state or a laterally opened state) where the upper case 2 is swung from the close state with respect to the lower case 3 about the axis b in the direction of arrow B (or the second direction, and a direction which is perpendicular to the first direction) as shown in FIG. 1(c).

Next, the configuration of the portable telephone 1 of the embodiment will be described with reference to FIG. 1.

The upper case 2 houses a receiver 5, a first displaying portion 7, and the like. The first displaying portion 7 is disposed on the principal surface 2A of the upper case 2. Although not illustrated, various circuits which realize a function of a portable telephone are mounted on a printed circuit board disposed in the upper case 2.

In the embodiment, the upper case 2 is made of a resin, but not restricted to this.

The lower case 3 houses a mouthpiece portion (microphone) 13, an operating portion 14, and the like. Although not illustrated, various circuits which realize a function of a portable telephone are mounted on a printed circuit board disposed in the lower case 3. The operating portion 14 which is exposed when the portable telephone 1 is in the first or second open state is disposed on the principal surface 3A of the lower case 3.

In the embodiment, similarly with the upper case 2, the lower case 3 is made of a resin, but not restricted to this.

The coupling portion 4 to which a first coupling portion 28 and a second coupling portion 29 are attached swingably couples the upper case 2 and the lower case 3 together. Although not illustrated, a wiring member (cable) which connects the printed circuit board of the upper case 2 with the second printed circuit board of the lower case 3 is passed through the coupling portion 4.

Although described later in detail, the second coupling portion 29 constitutes a part of a display device holding apparatus 10 which is one characteristic of the invention.

Next, the lower case 3 will be described in detail. The microphone 13 is disposed in the principal surface 3A of the lower case 3 so as to, when the portable telephone 1 is in the close state, be opposed to and covered by the upper case 2, and, when the portable telephone 1 is in the first or second open state, be exposed. In a calling operation, a voice of the user is transmitted to a communication counterparty.

The operating portion 14 is placed in the principal surface 3A of the lower case 3. Numerals, characters, and symbols are printed in order to allow a telephone number or characters to be input. The operating portion is configured by, for example, a plurality of operation buttons through which call reception, call termination, adjustment of the volume which is output through the receiver 5 or the like, switching to the vibration mode, selection and determination on a menu screen, and the like can be performed.

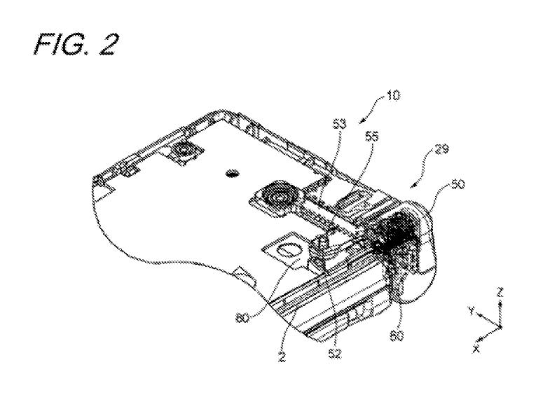

Next, the display device holding apparatus 10 which is disposed in the portable telephone 1 will be described with reference to FIGS. 2 to 5. FIG. 2 is a perspective view of the display device holding apparatus 10. The display device holding apparatus 10 shown in FIG. 2 is configured by the second coupling portion 29 and a sheet metal which is molded integrally with a part of the upper case 2. FIG. 2 shows the vicinity of the second coupling portion 29 inside the upper case 2 in the close state shown in FIG. 1(a).

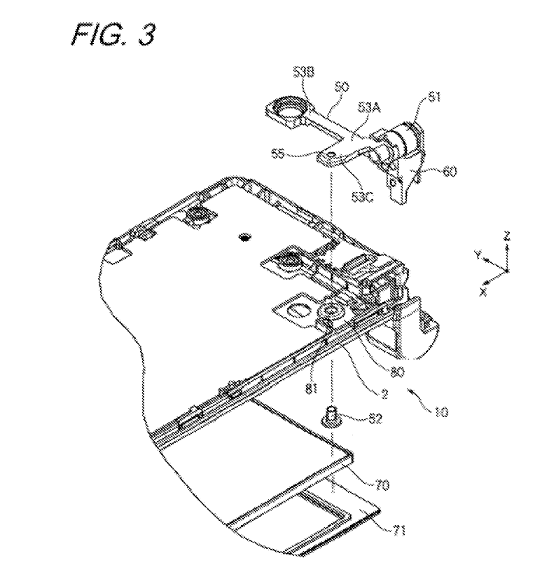

As shown in FIG. 3, the second coupling portion 29 which is housed in the coupling portion 4 is configured by a swing shaft member 50 and a holding member 60. The second coupling portion 29 is requested to have high rigidity, and hence formed by a metal material.

As shown in FIGS. 2 and 3, the swing shaft member 50 is formed to have a shaft portion 51, an arm portion 53 which is formed so as to be perpendicular to the shaft portion 51, and a first screw hole portion 55 which is formed in the arm portion 53, and which is fixed to the upper case 2 by a screw 52.

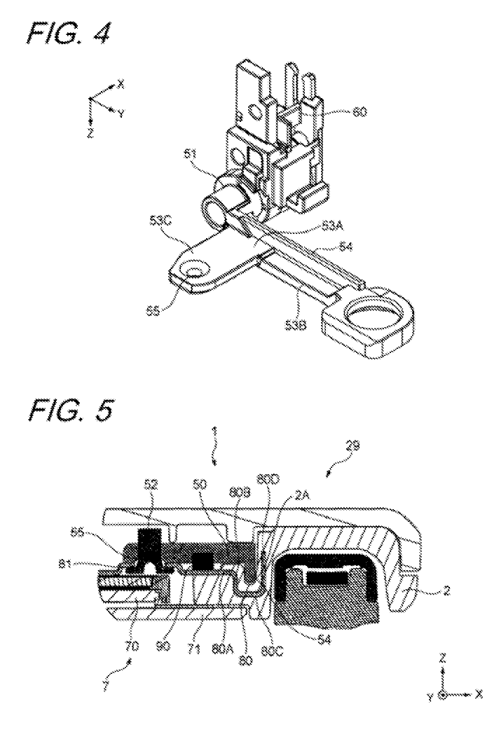

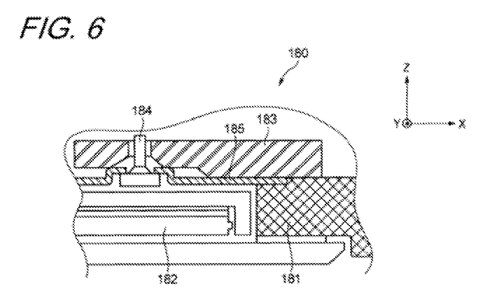

In the swing shaft member 50 constituting the second coupling portion 29, as shown in FIGS. 3 and 4, the arm portion 53 is configured by: a basal portion 53A; a first extending portion 53B which extends from the basal portion 53A in the short direction (in the figure, the Y-axis direction) of the upper case 2; and a second extending portion 53C which extends from the basal portion 53A in the longitudinal direction (the X-axis direction in the figure) of the upper case 2.

The configuration of the arm portion 53 will be described with reference to FIG. 4. FIG. 4 is a view as seeing the swing shaft member 50 from the rear side. In the arm portion 53, as shown in FIG. 4, the basal portion 53A and the first extending portion 53B are formed into a substantially L-like shape in the thickness direction (in the figure, the Z-axis direction) of the upper case 2.

As shown in FIG. 4, a rib 54 which is formed into a substantially L-like shape is disposed on one-side surfaces of the basal portion 53A and the first extending portion 53B. In the short direction (in the figure, the Y-axis direction) of the upper case 2, the rib 54 extends from an end part of the basal portion 53A which is close to the shaft portion 51, to the tip end of the first extending portion 53B. The rib 54 of the arm portion 53 is engaged with a groove 2A which is disposed in the resin-made upper case 2 that will be described later, to be fixed to the upper case 2. The rib 54 which is a part of the metal-made swing shaft member 50 is engaged with the resin-made upper case 2, whereby the strength of the resin-made upper case 2 is enhanced. The shape of the groove 2A which is disposed in the resin-made upper case 2 is formed so as to correspond to that of the rib 54 of the arm portion 53 which is engaged therewith.

As shown in FIG. 4, moreover, the first screw hole portion 55 which is to be fixed to the upper case 2 by the screw 52 is disposed in the tip end of the second extending portion 53C.

As shown in FIG. 3, the swing shaft member 50 is fixed to the upper case 2 without any rattling by the rib 54 of the arm portion 53 which is engaged with the groove 2A disposed in the upper case 2, and the screw 52 which is) inserted into the first screw hole portion 55.

The holding member 60 shown in FIGS. 3 and 4 swingably holds and supports the shaft portion 51 of the swing shaft member 50, thereby enabling the swing shaft member 50 to be swingably attached to the holding member 60. The holding member 60 is attached to the upper case 2.

The sheet metal 80 which is shown in FIG. 3, and which is integrally molded holds a display device 70 constituting the first displaying portion 7 that is housed in the upper case 2. A display panel 71 is a transparent panel which is stacked on the display device 70 to protect the display device 70. In the integrally molded sheet metal 80, a screw hole 81 through which the screw 52 is to be passed is disposed at a position corresponding to the first screw hole portion 55 of the swing shaft member 50.

Next, the positional relationship between the integrally molded sheet metal 80, and the rib 54 of the arm portion 53 will be described with reference to FIG. 5. FIG. 5 is a partial sectional view taken along line V-V in FIG. 1, and shows a section which is taken along the longitudinal direction (in the figure, the X-axis direction) of the upper case 2, and which contains the screw hole 55 of the swing shaft member 50.

As shown in FIG. 5, starting from the first displaying portion 7 which is housed in the upper case 2, the display panel 71 and the display device 70 are stacked in this sequence along the thickness direction (the Z-axis direction in the figure) of the upper case 2, and the integrally molded sheet metal 80 holds the display device 70.

Then, the integrally molded sheet metal 80 holds the display device 70.

As shown in FIG. 5, the display panel 71 extends to an end part of the upper case 2 which is close to the second coupling portion 29, in the longitudinal direction (in the figure, the X-axis direction) of the upper case 2.

In the case where, as in the conventional example, the insert-molded sheet metal 185 is simply linearly disposed along the longitudinal direction of the case 181, when the total length of the display device 182 is increased in the longitudinal direction of the case 181 without changing the total length of the case 181 as far as possible, the strength of the case 181 cannot be sufficiently ensured, and the display device 182 cannot be held with sufficient strength. In the embodiment, by contrast, the portion where the integrally molded sheet metal 80 is engaged with the upper case 2 has the following configuration, and the strength of the upper case 2 can be sufficiently ensured. In the embodiment, therefore, the display device can be held with sufficient strength.

As shown in FIG. 5, in a section which is taken along the thickness direction (the Z-axis direction in the figure) of the upper case 2, an end portion of the sheet metal 80 which is molded integrally with the upper case 2, on the side of the second coupling portion 29 is configured by: a basal end portion 80A which extends into the upper case 2 along the longitudinal direction (in the figure, the X-axis direction) of the upper case 2; a first portion 80B which extends from one end of the basal end portion 80A in the longitudinal direction (in the figure, the X-axis direction) of the upper case 2, along the thickness direction (in the figure, the Z-axis direction) of the upper case 2; a second portion 80C which extends from one end of the first portion 80B along the longitudinal direction (in the figure, the X-axis direction) of the upper case 2; and a third portion 80D which extends from one end of the second portion 80C along a direction that is substantially parallel to the first portion.

As described above, the sheet metal 80 which is molded integrally with the upper case 2 has: the first portion 80B which extends along the thickness direction (in the figure, the Z-axis direction) of the upper case 2; the second portion 80C which is bent from the first portion, and which extends along the longitudinal direction (in the figure, the X-axis direction) of the upper case 2; and the third portion 80D which is bent from the second portion, and which extends along a direction that is substantially parallel to the first portion. Therefore, the strength of the upper case 2 can be sufficiently ensured, and the display device can be held with sufficient strength.

In the integrally molded sheet metal 80, the two part, i.e., the part between the first portion 80B and the second portion 80C, and that between the second portion 80C and the third portion 80D are bent. However, the configuration is not limited to this, and requested to have at least one bent part. As the number of bent parts in the integrally molded sheet metal 80 is larger, the strength of the portion of the upper case 2 in which the sheet metal 80 is integrally molded is further enhanced.

In the section which is taken along the thickness direction (the Z-axis direction in the figure) of the upper case 2, in the end portion of the integrally molded sheet metal 80, on the side of the second coupling portion 29, as shown in FIG. 5, the groove 2A of the upper case 2 which is formed so as to extend from the interior of the upper case 2 toward the surface where the first displaying portion 7 is formed is disposed in a portion which is surrounded by the first portion 80B, the second portion 80C, and the third portion 80D, and which has a substantially U-like shape. Then, the rib 54 of the arm portion 53 is engaged with the groove 2A of the upper case 2. In the end portion of the integrally molded sheet metal 80 on the side of the second coupling portion 29, therefore, the portion which is surrounded by the first portion 80B, the second portion 80C, and the third portion 80D, and which has a substantially U-like shape can be further reinforced by the rib 54 of the arm portion 53 which constitutes a part of the second coupling portion 29.

As described above, according to the display device holding apparatus 10 of the embodiment, and the portable telephone 1 having it, the strength of the upper case 2 can be sufficiently ensured, and the display device can be held with sufficient strength.

As shown in FIG. 5, in the section which is taken along the thickness direction (the Z-axis direction in the figure) of the upper case 2, the rib 54 of the arm portion 53 is engaged with the groove 2A of the upper case 2, and the screw 52 is inserted into the first screw hole portion 55 through the screw hole 81 of the sheet metal 80 which is molded integrally with the upper case 2, along the direction (in the figure, the Z-axis direction) which is oriented from the surface where the first displaying portion 7 is formed, toward the interior of the case, whereby the swing shaft member 50 is screwingly fixed. The upper case 2 including the integrally molded sheet metal 80, and the swing shaft member 50 are screwed as described above, whereby rattling between the swing shaft member 50 and the upper case 2 can be prevented from occurring.

As shown in FIG. 5, in order to stabilize the antenna characteristics of the portable telephone 1, an electrically conductive cushion 90 is disposed between the basal end portion 80A of the sheet metal 80 which is molded integrally with the upper case 2, and the arm portion 53 of the swing shaft member 50, so that a contact between the integrally molded sheet metal 80 and the swing shaft member 50 is ensured.

Although the invention has been described in detail and with reference to the specific embodiment, it is obvious to those skilled in the art that various changes and modifications can be made without departing from the spirit and scope of the invention.

The application is based on Japanese Patent Application No. 2009-242600 filed Oct. 21, 2009, and its disclosure is incorporated herein by reference.

### INDUSTRIAL APPLICABILITY

The display device holding apparatus of the invention, and the portable terminal having it have an effect that, even when the total length of a display device is increased, the strength of a case can be sufficiently ensured without increasing the total length of the case itself, and are useful as a portable telephone or the like.

### DESCRIPTION OF REFERENCE NUMERALS AND SIGNS

2 upper case
2A groove
4 coupling portion
7 first displaying portion
10 display device holding apparatus
29 second coupling portion
50 swing shaft member
52 screw
53 arm portion
54 rib
55 first screw hole portion
70 display device
71 display panel
80 sheet metal
80B first portion
80C second portion
80D third portion
81 screw hole

1. A display device holding apparatus comprising:
a first case;
a display device which is disposed in the first case;
a coupling portion which has a rib extending in a thickness direction of the first case, and which swingably couples a second case to the first case; and
a sheet metal which has: a first portion that is placed in the first case, and that is substantially parallel to the thickness direction of the first case; a second portion that extends from the first portion in a longitudinal direction of the first case; and a third portion that extends from the second portion substantially parallel to the first portion, the sheet metal being molded integrally with a part of the first case,
the rib is engaged with a groove disposed in the first case between the first portion and the third portion in the longitudinal direction of the first case, and the coupling portion and at least a part of the sheet metal hold the display device.

2. A portable terminal wherein the portable terminal includes a display device holding apparatus according to claim 1.
